(19) United States
(12) Patent Application Publication
(10) Pub. No.: US 2025/0189559 A1
(43) Pub. Date: Jun. 12, 2025

(54) PROBE, PROBE CARD, AND PROBE MANUFACTURING METHOD

(71) Applicant: JAPAN ELECTRONIC MATERIALS CORPORATION, Amagasaki-shi, Hyogo (JP)

(72) Inventor: Chikaomi MORI, Amagasaki-shi, Hyogo (JP)

(73) Assignee: JAPAN ELECTRONIC MATERIALS CORPORATION, Amagasaki-shi, Hyogo (JP)

(21) Appl. No.: 18/846,182

(22) PCT Filed: Mar. 30, 2022
(86) PCT No.: PCT/JP2022/016176

§ 371 Date: Sep. 11, 2024

(51) Int. Cl. G01R 1/073; G01R 3/00

(52) U.S. Cl. CPC G01R 1/07342; G01R 3/00

(57) ABSTRACT

This probe includes: a first metal portion and a plate-shaped second metal portion. On one end side in a longitudinal direction X of the first metal portion, the second metal portion is buried along the longitudinal direction in a predetermined range, and protrudes in the longitudinal direction from the first metal portion so as to have a contact portion to contact with an electrode of a semiconductor device. A cross-section of the contact portion perpendicular to the longitudinal direction has a circular shape, and a cross-section perpendicular to the longitudinal direction at an end of the second metal portion on a side opposite to the contact portion in the longitudinal direction has a rectangular shape.

### TECHNICAL FIELD

The present disclosure relates to a probe, a probe card, and a probe manufacturing method.

### BACKGROUND ART

A probe card is a component of an inspection device for inspecting electrical characteristics of semiconductor devices. The probe card has multiple probes to contact with electrodes of semiconductor devices. Characteristics inspection for semiconductor devices is performed by bringing a semiconductor wafer close to the probe card so that contact portions of the probes contact with electrodes on the semiconductor devices and performing current conduction between a tester device and the semiconductor devices via the probes.

In recent years, as semiconductor devices are more finely formed, the sizes of electrodes thereof have also been reduced. Along with reduction of the electrode sizes, a probe and a contact portion of the probe need to be manufactured as finely as possible. In addition, the contact portion is required to have wear resistance.

Accordingly, proposed is a structure including a needle body portion having a connection end to a circuit of a probe board and formed of a first metal material having toughness, and a needle tip portion having a needle tip and formed of a second metal material having higher hardness than the first metal material of the needle body portion, the needle tip portion being contiguous to the needle body portion. The needle body portion and the needle tip portion are provided with a current path formed of the same metal material and leading from the needle tip to the connection end. In this structure, durability of the tip is enhanced by using hard metal for the contact portion.

### CITATION LIST

### Patent Document

Patent Document 1: Japanese Laid-Open Patent Publication No. 2013-246116

### SUMMARY OF THE INVENTION

### Problem to be Solved by the Invention

A probe disclosed in Patent Document 1 is manufactured by so-called MEMS (Micro Electro Mechanical Systems). In this case, due to constraints of a manufacturing apparatus, there is naturally a limitation in narrowing a width in a direction perpendicular to the lamination direction of metal films and therefore it is difficult to make the width smaller than 10 μm. As a result, there is a problem that it is also difficult to form a finer-sized probe and a tip shape of a sharp contact portion thereof.

The present disclosure has been made to solve the above problem, and an object of the present disclosure is to provide a probe, a probe card, and a probe manufacturing method that can achieve a finer probe size, maintain a sharpened tip shape even after repetition of contact with an electrode of a semiconductor device, and achieve high contact performance and high durability.

### Means to Solve the Problem

A probe according to the present disclosure includes: a first metal portion made of first metal having conductivity; and a plate-shaped second metal portion made of second metal having conductivity and harder than the first metal portion, the second metal portion being buried in the first metal portion and protruding from a tip of the first metal portion so as to have a contact portion to contact with an inspection target. The contact portion has such a flattened and sharpened tongue shape that a contour of a tip portion in a first cross-section along a protruding direction of the second metal portion has a first parabolic shape and a contour of the tip portion in a second cross-section along the protruding direction and perpendicular to the first cross-section has a second parabolic shape different from the first parabolic shape.

A probe card according to the present disclosure includes a plurality of the above probes.

A probe manufacturing method according to the present disclosure includes: a probe intermediate body formation step of forming a probe intermediate body in which, on one end side of a first metal portion made of a first metal having conductivity, a second metal portion made of second metal having conductivity and harder than the first metal portion is buried in a plate shape; and a polishing step of thrusting the one end side of the first metal portion of the probe intermediate body into an abrasive, to perform polishing so that the second metal portion protrudes from the first metal portion and a protruding tip has such a flattened and sharpened tongue shape that a contour of a tip portion in a first cross-section along a protruding direction of the second metal portion has a first parabolic shape and a contour of a tip portion in a second cross-section along the protruding direction and perpendicular to the first cross-section has a second parabolic shape different from the first parabolic shape.

### Effect of the Invention

With the probe, the probe card, and the probe manufacturing method according to the present disclosure, it becomes possible to provide a probe, a probe card, and a probe manufacturing method that can maintain a sharpened tip shape even after repetition of contact with an electrode of a semiconductor device formed at a semiconductor wafer, achieve high contact performance in contact with the electrode, and achieve high durability.

### BRIEF DESCRIPTION OF THE DRAWINGS

FIG. 1 schematically shows a state in which semiconductor devices are inspected by a probe card according to embodiment 1.

FIG. 2 is a perspective view of a tip portion including a contact portion of a probe according to embodiment 1.

FIG. 3A is a sectional view along line A-A in FIG. 2. FIG. 3B is a sectional view along line B-B in FIG. 2. FIG. 3C is an enlarged view of a specific part in FIG. 3A. FIG. 3D is an enlarged view of a specific part in FIG. 3B.

FIG. 4A is a sectional view when a probe intermediate body to be a probe is cut perpendicularly to a longitudinal direction at a part formed by a hard portion and a soft portion. FIG. 4B is a sectional view along line D-D in FIG. 4A. FIG. 4C is a sectional view along line C-C in FIG. 4A.

FIG. 5A is a schematic sectional view showing the structure of a first resist layer. FIG. 5B is a schematic sectional view showing a first plating layer formation step. FIG. 5C is a schematic sectional view showing the structure of a second resist layer. FIG. 5D is a schematic plan view of the second resist layer. FIG. 5E is a schematic sectional view showing a second plating layer formation step.

FIG. 6A is a schematic sectional view showing a state in which the first and second resist layers are removed. FIG. 6B is a schematic sectional view showing the structure of a third resist layer. FIG. 6C is a schematic sectional view showing a third plating layer formation step. FIG. 6D is a schematic sectional view of a probe intermediate body completed with the third resist layer removed.

FIG. 7 shows a polishing step for the probe intermediate body according to embodiment 1.

### DESCRIPTION OF EMBODIMENTS

### Embodiment 1

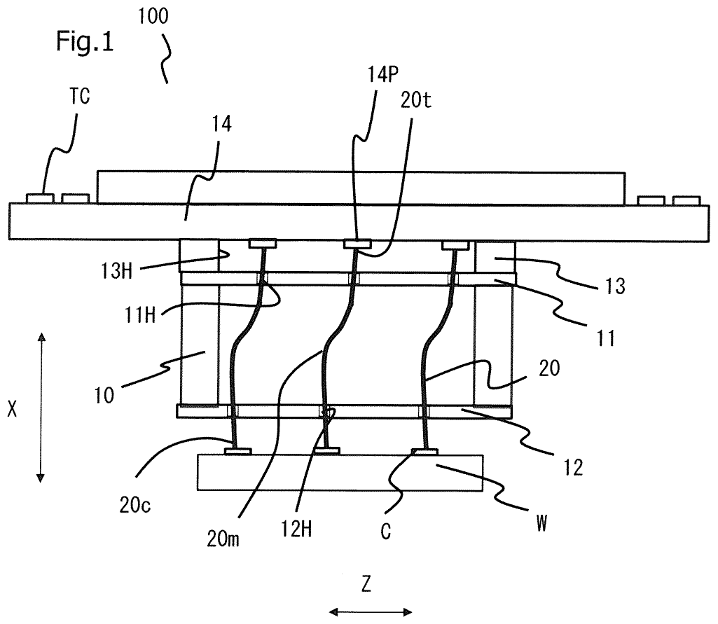

Hereinafter, a probe, a probe card, and a probe manufacturing method according to embodiment 1 will be described with reference to the drawings. In the description, the upper side of the drawing sheet in FIG. 1 is defined as “up”, and the lower side of the drawing sheet is defined as “down”. That is, as seen from a probe card, a side where a semiconductor device as an inspection target is present is defined as “down”.

FIG. 1 schematically shows a state in which semiconductor devices are inspected by a probe card 100 according to embodiment 1.

The probe card 100 is a device used for inspecting electrical characteristics of semiconductor devices formed at a semiconductor wafer W. The probe card 100 includes multiple probes 20 to contact with electrodes C on the semiconductor devices formed at the semiconductor wafer W. Characteristics inspection for the semiconductor devices is performed by bringing the probe card 100 close to the semiconductor wafer W so that tips of the probes 20 contact with the electrodes C on the semiconductor devices and performing current conduction between a tester device (not shown) and tester connection electrodes TC on a wiring board 14 of the probe card 100 via the probes 20.

The probe card 100 includes a hollow frame 10, an upper guide 11 attached to the upper end of the frame 10, a lower guide 12 attached to the lower end of the frame 10, a fixation plate 13 fixing the upper guide 11, and the wiring board 14.

The upper guide 11 has a plurality of guide holes 11H penetrating in the up-down direction, and the lower guide 12 provided below the upper guide 11 also has a plurality of guide holes 12H penetrating in the up-down direction. An opening 13H provided in the fixation plate 13 is present above the plurality of guide holes 11H provided in the upper guide 11. The wiring board 14 is provided on the upper surface of the fixation plate 13. The wiring board 14 has, on a lower surface thereof, a plurality of probe connection pads 14P contacting with the upper ends of the probes 20.

A plurality of probes 20 are guided by being inserted through the guide holes 12H and the guide holes 11H. The probes 20 are vertical-type probes placed perpendicularly to the inspection targets (semiconductor devices).

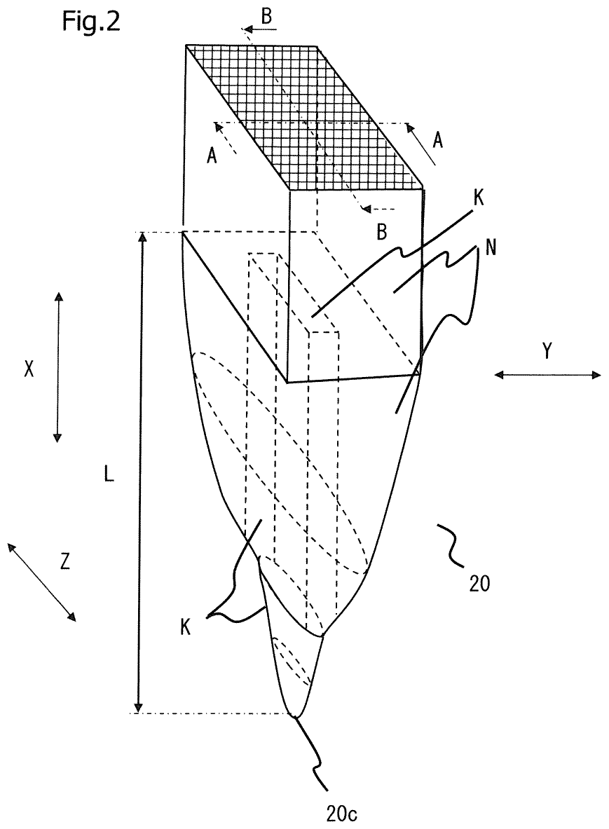

FIG. 2 is a perspective view of a tip portion including a contact portion 20c of the probe 20.

This is a perspective view of the tip portion cut perpendicularly to a longitudinal direction X of the probe 20, as seen from the cross-section side.

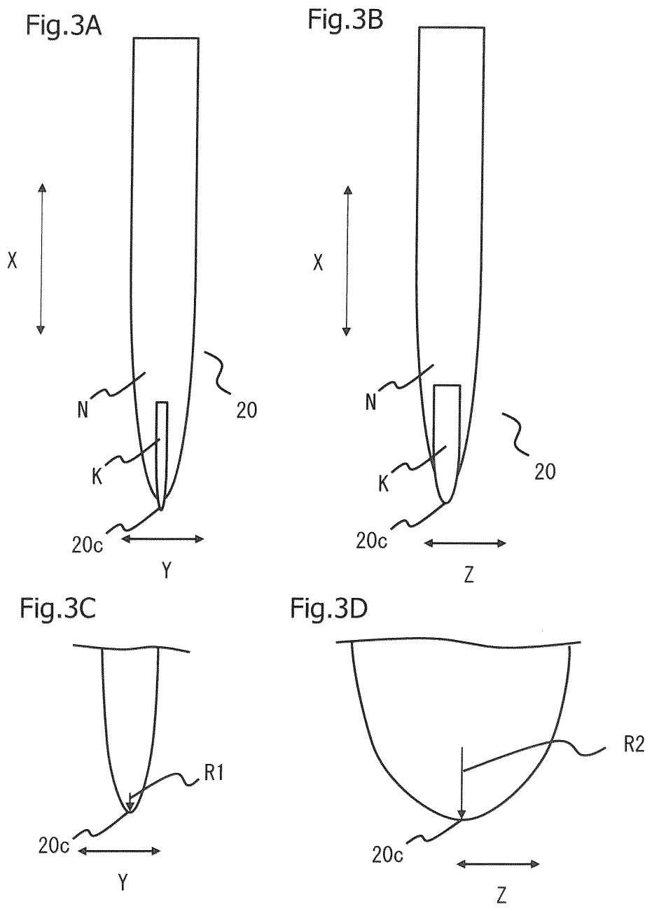

FIG. 3A is a sectional view along line A-A in FIG. 2 when a lower part of the probe 20 is cut along a plane passing the center axis thereof and in a direction Y (second direction) perpendicular to a buckling direction Z (first direction).

FIG. 3B is a sectional view along line B-B in FIG. 2 when the lower part of the probe 20 is cut along a plane passing the center axis thereof and in the buckling direction Z.

FIG. 3A and FIG. 3B show a part of the probe 20 on the contact portion 20c side.

FIG. 3C is an enlarged view of a specific part in FIG. 3A. FIG. 3D is an enlarged view of a specific part in FIG. 3B.

As shown in FIG. 1 to FIG. 3, the probe 20 is made of conductive metal, the cross-section thereof perpendicular to the longitudinal direction X (which is also a contact direction to the electrode C) has a rectangular shape except near the contact portion 20c at the lower tip, and the probe 20 has a thin elongated shape. A center part is curved, and an upper part and a lower part extend linearly in the up-down direction. The curved center part is an elastically-deformable portion 20m. The probe 20 has the contact portion 20c pointed downward, at a lower end (one end) thereof. The probe 20 has a terminal portion 20t at an upper end (another end) thereof.

The contact portion 20c is a portion to contact with an inspection target. The terminal portion 20t is provided at the upper end of the probe 20 and is pressed in contact with the probe connection pad 14P of the wiring board 14 at the time of inspection. The elastically-deformable portion 20m is a part to be easily buckled by a compressive force being applied in the longitudinal direction X at the time of so-called overdrive. At the time of overdrive, the elastically-deformable portion 20m buckles in the buckling direction Z in accordance with a reaction force from the inspection target, so that the contact portion 20c recedes toward the terminal portion 20t side. The buckling direction Z is the right-left direction in FIG. 1.

In a predetermined range L from the lower tip of the probe 20, the probe 20 is formed of two kinds of conductive metals different in hardness. In FIG. 2, a hard portion K (second metal) is a part formed by a hard metal film, and a soft portion N (first metal) is a part formed by metal softer than the hard portion K. As shown in FIG. 2, the hard portion K is buried in the soft portion N along the longitudinal direction X of the probe 20, and the hard portion K including the contact portion 20c at the tip protrudes downward from the soft portion N so as to be exposed. The part in the range other than the range L is all formed by the soft portion N.

As shown in FIG. 3A to FIG. 3D, the contact portion 20c exhibits a parabolic shape in each cross-section at the tip. Regarding the radius of curvature at the vertex of the contact portion 20c, a radius R2 of curvature in the cross-section along the buckling direction Z is greater than a radius R1 of curvature in the cross-section along the direction Y perpendicular to the buckling direction Z. Preferably, the ratio of R1:R2 is about 1:2 to 1:4.

The electrode C of the semiconductor device may be coated with an oxide film. In characteristics inspection for the semiconductor device, the probe 20 buckles in the buckling direction Z at the time of overdrive, so that the contact portion 20c receives a reaction force from the elastically-deformable portion 20m. In view of a relationship with the buckling direction Z, in a case where the contact portion 20c of the probe 20 contacts with the electrode C on the semiconductor device over a long range in the buckling direction Z and a short range in the direction Y perpendicular to the buckling direction Z, the contact portion 20c more scrapes the oxide film formed on the electrode C, thus ensuring sufficient electric contact. For this reason, the contact portion 20c is formed in a flattened and sharpened tongue shape, so as to contact with the electrode C sharply and over a longer range in the buckling direction Z.

The probe 20 is manufactured using so-called MEMS (Micro Electro Mechanical Systems) (probe intermediate body formation step). The MEMS is technology of forming a fine three-dimensional structure by using photolithography and sacrificial layer etching. The photolithography is technology used in a semiconductor manufacturing process or the like to work a fine pattern by using a photoresist. The sacrificial layer etching is technology in which a lower layer called a sacrificial layer is formed, a layer for forming a structure is formed thereon, and then only the sacrificial layer is removed by etching, thereby forming a three-dimensional structure.

In processing for forming each layer, known plating technology may be used. For example, a board as a cathode and a metal piece as an anode are immersed in an electrolyte solution, and then voltage is applied between both electrodes, whereby metal ions in the electrolyte solution can be deposited on the board surface. Such processing is called electroplating and is a wet process of immersing a board in an electrolyte solution. Therefore, after the plating, drying processing is performed to obtain a probe intermediate body. After the drying processing, a part to be the lower tip is polished by polishing processing described later (polishing step), to form the contact portion 20c.

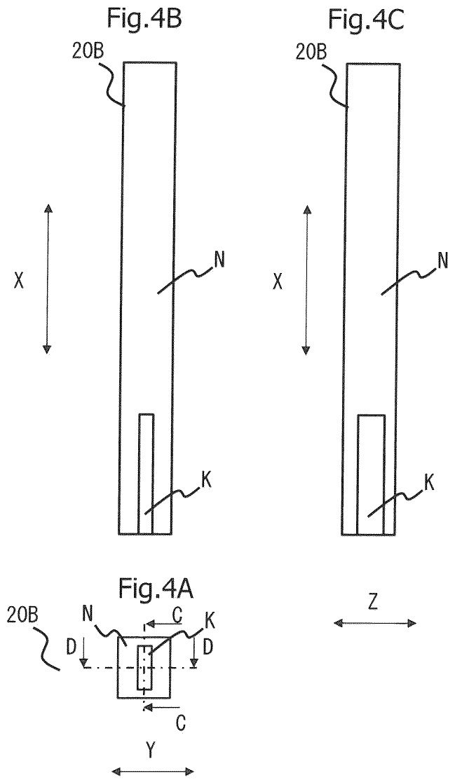

FIG. 4A to FIG. 4C are sectional views of a probe intermediate body 20B before the polishing processing. The probe intermediate body 20B is manufactured using the above-described MEMS. The probe intermediate body 20B is a metal laminated body before the polishing processing for the contact portion 20c.

FIG. 4A is a sectional view when the probe intermediate body 20B to be the probe 20 is cut perpendicularly to the longitudinal direction X at a part formed by the hard portion K and the soft portion N.

FIG. 4B is a sectional view along line D-D in FIG. 4A. FIG. 4C is a sectional view along line C-C in FIG. 4A.

Using the above-described MEMS, the probe intermediate body 20B is formed as a laminated body of two kinds of conductive metals such that the hard portion K having a predetermined length is buried in the soft portion N along the longitudinal direction X at one end of the probe 20. At this time, the outer appearance of the probe intermediate body 20B has a thin elongated rectangular parallelepiped shape, and the cross-section thereof perpendicular to the longitudinal direction X has a rectangular shape at any part. The end surface of the hard portion K also has a rectangular shape, and the length of a side in the buckling direction Z of the rectangular shape is greater than the length of a side perpendicular to the buckling direction Z. The ratio of the long side and the short side is about 2:1, and in the present embodiment, the long side is 10 μm and the short side is 5 μm.

Of the probe intermediate body 20B, the material of the hard portion K is rhodium (Rh). In addition, the material of the soft portion N is a nickel alloy or the like.

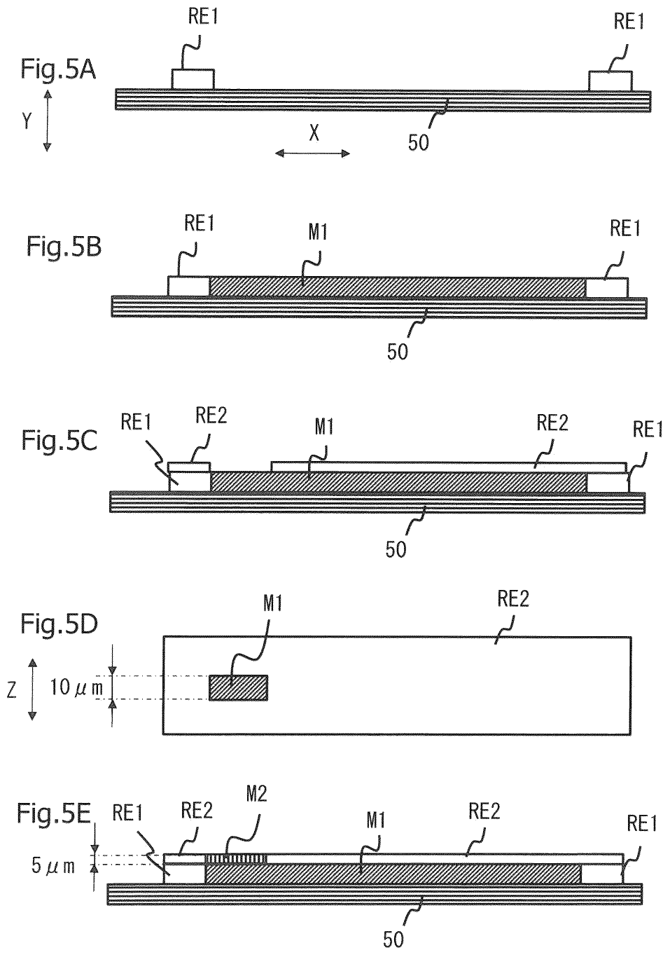

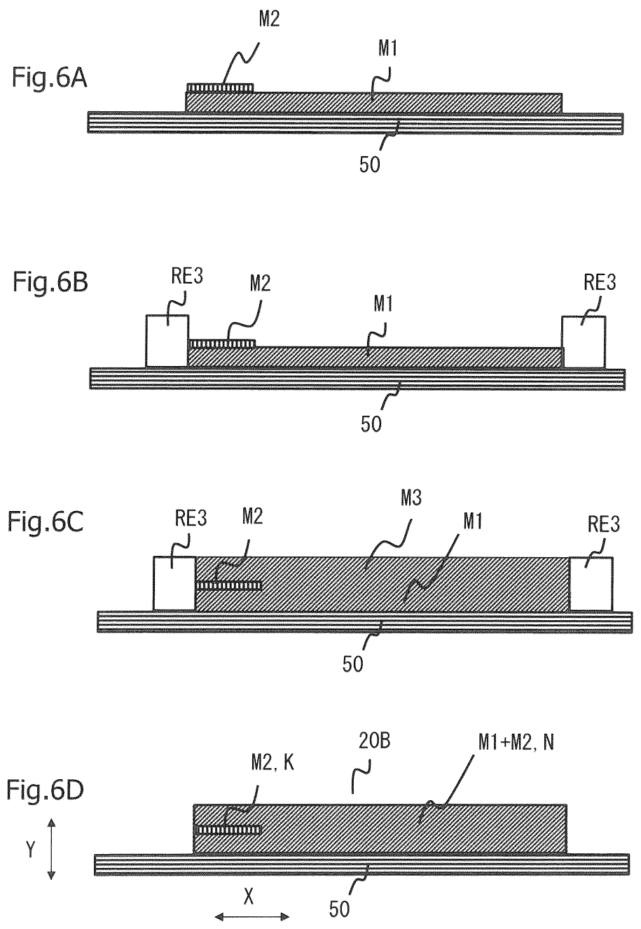

FIG. 5 and FIG. 6 are schematic sectional views showing a manufacturing process for the probe intermediate body 20B.

FIG. 5A shows arrangement of a first resist layer RE1.

In description of the manufacturing process for the probe intermediate body 20B, a resist layer refers to a resist layer which has been cured through development processing and from which a surplus part has been removed. In the manufacturing process for the probe intermediate body 20B, the direction Y perpendicular to the buckling direction Z described above is a lamination direction of metal plating.

First, as shown in FIG. 5A, on a base 50 made of stainless steel and having a flat surface, the first resist layer RE1 is formed in an enclosing manner with the same shape as the outer periphery of the probe intermediate body 20B shown in FIG. 4C (first resist layer formation step). Next, in the opening of the first resist layer RE1, a first plating layer M1 is formed by the first metal to be the soft portion N (first plating layer formation step).

FIG. 5C is a schematic sectional view showing the structure of a second resist layer RE2. FIG. 5D is a schematic plan view of the second resist layer RE2. Next, on the first plating layer M1, the second resist layer RE2 is formed so as to open only in a range for forming a second plating layer M2 to be the hard portion K and cover the other part of the first plating layer M1 (second resist layer formation step).

FIG. 5E shows a state in which the second plating layer M2 is formed. Next, as shown in FIG. 5E, in the opening of the second resist layer RE2, the second plating layer M2 is formed by the second metal to be the hard portion K (second plating layer formation step). The thickness of the second plating layer M2 is about 5 μm, and the width thereof in the buckling direction Z described above is about 10 μm.

Next, as shown in FIG. 6A, the first resist layer RE1 and the second resist layer are removed (first and second resist layer removal step). Next, as shown in FIG. 6B, a third resist layer RE3 having the same height as the lamination thickness of the probe intermediate body 20B is formed so as to enclose the periphery of the first plating layer M1 (third resist layer formation step). Next, as shown in FIG. 6C, in the opening of the third resist layer RE3, a third plating layer M3 is formed by the first metal (third plating layer formation step). At this time, the first plating layer M1 and the third plating layer M3 are integrated. Next, as shown in FIG. 6D, the third resist layer is removed. As a result, the probe intermediate body 20B in which the thin-plate-shaped hard portion K whose cross-section has a rectangular shape of 5 μm×10 μm is buried at one end of the soft portion N, is obtained.

Next, the polishing step for the probe 20 will be described.

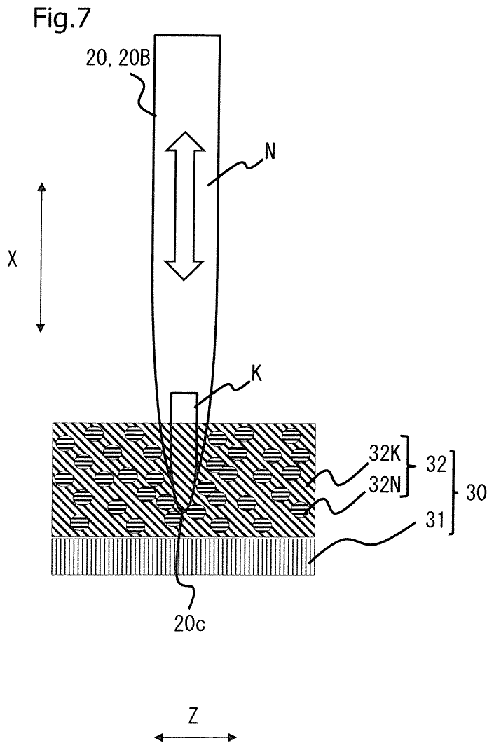

FIG. 7 is a conceptual view showing the polishing step for the probe intermediate body 20B. For convenience of description, the same cross-section as in FIG. 4C is shown also in FIG. 7.

Of the probe intermediate body 20B, an end where the hard portion K is buried is polished using an abrasive 30.

The abrasive 30 includes an abrasive sheet base 31 and an abrasive sheet 32 formed thereon. The abrasive sheet 32 is formed such that hard abrasive particles 32K of diamond or the like are uniformly dispersed in a soft binder 32N. The end of the probe intermediate body 20B where the hard portion K is buried is repeatedly thrust into the abrasive 30 so as to be polished, thus obtaining the probe 20 polished so that the contact portion 20c protrudes in a flattened and sharpened tongue shape in the longitudinal direction X from the soft portion N. The cross-section perpendicular to the longitudinal direction X at the end of the hard portion K on the side opposite to the contact portion 20c in the longitudinal direction X remains having a rectangular shape.

As shown in FIG. 7, when the probe intermediate body 20B is thrust into the abrasive 30, through the stroke, a part of the soft portion N close to a part to be the contact portion 20c at the tip is polished by the abrasive 30 for a longer time. As a result, the soft portion N at the tip of the probe intermediate body 20B is all removed through polishing, so that the buried hard portion K is exposed. As the polishing is continued, the soft portion N and the exposed hard portion K are polished at the same time. This results in obtaining such a shape that the hard portion K polished in a flattened and sharpened tongue shape protrudes from the soft portion N left after the polishing.

As shown in FIG. 4A, the cross-section perpendicular to the longitudinal direction X at the tip portion of the probe intermediate body 20B before polishing has a rectangular shape which is longer in the buckling direction Z than in the direction Y perpendicular to the buckling direction Z, and the hard portion K also has a similar sectional shape. Therefore, as seen from both of the buckling direction Z and the direction Y perpendicular to the buckling direction Z, the tip shape on the contact portion 20c side of the probe 20 after polishing has a parabolic contour shape and thus has a sharpened tongue shape flattened in the buckling direction Z as described above.

With the probe 20, the probe card 100, and the manufacturing method for the probe 20 according to embodiment 1, a thin plate (hard portion K, second metal portion) having a rectangular sectional shape and made of the hard second metal whose width is a limit width in fine structure made by the MEMS is buried in the first metal portion (soft portion N) made of the first metal softer than the second metal by using the MEMS, to obtain the probe intermediate body. Then, the side where the second metal portion is buried is polished, thus obtaining a probe or a probe pin having the contact portion 20c made of the second metal and sharpened more finely than 10 μm which is the limit width in fine structure made by the MEMS, and also, such a probe pin manufacturing method can be provided.

In addition, since the fine hard portion K can be polished in a state of being surrounded by the soft portion N, both portions can be polished at the same time with the soft portion N used as a support member for the hard portion K, whereby the contact portion 20c having the sharpened hard portion K can be formed.

In addition, the contact portion 20c has a flattened and sharpened tongue shape at the tip while the sectional shape perpendicular to the longitudinal direction X is not a rectangular shape (the sectional shape perpendicular to the longitudinal direction X is an elliptic shape). Thus, it is possible to provide such a probe that the sharpened tip shape can be maintained even after repetition of contact with the electrode C of the semiconductor device, contact performance in contact with the electrode C of the semiconductor device is high, and durability is high.

In addition, the sharpened contact portion 20c which is longer in the buckling direction Z than in the direction Y perpendicular to the buckling direction Z can be brought into contact with the electrode C of the semiconductor device. Thus, at the time of overdrive of the probe 20, the oxide film on the electrode C is scraped by the contact portion 20c, whereby the contact surface pressure with the electrode C per unit area can be ensured to be appropriate.

In addition, since the contact portion 20c has a sharpened tongue shape, the contact area expands to sharpened parts on both sides even when the tip is worn, and thus durability is high.

In addition, the sectional area of the cross-section perpendicular to the longitudinal direction X of the probe 20 can be ensured by the soft portion N to a position near the sharpened contact portion 20c, whereby current withstanding performance can be ensured. Thus, current withstanding performance and the strength of the contact portion 20c can be both achieved.

Since the contact area expands, durability is high.

In addition, since the elastically-deformable portion 20m is formed by only the soft portion N softer than the hard portion K, elasticity needed for buckling can be ensured.

In addition, with the manufacturing method for the probe 20 according to embodiment 1, the width in the buckling direction Z of the hard portion and the width in the direction Y perpendicular to the buckling direction Z can be easily adjusted by the MEMS, whereby the strength of the contact portion 20c and the above-described sectional area can be freely adjusted.

In addition, by adjusting the stroke length in the up-down direction and the number of times of stroke in polishing, it is possible to form the contact portion 20c having precisely the same tongue shape from the probe intermediate body 20B without being influenced by the quality of the abrasive 30. Thus, the probe 20 that is highly precise can be provided.

The tip shape of the probe and the probe manufacturing method described in the present embodiment are also applicable to a probe and a probe card of a cantilever type. In this case, the longitudinal direction X described above can be replaced with the contact direction of the contact portion of the probe.

Although the disclosure is described above in terms of an exemplary embodiment, it should be understood that the various features, aspects, and functionality described in the embodiment are not limited in their applicability to the particular embodiment with which they are described, but instead can be applied alone or in various combinations to the embodiment of the disclosure.

It is therefore understood that numerous modifications which have not been exemplified can be devised without departing from the scope of the present disclosure. For example, at least one of the constituent components may be modified, added, or eliminated.

### DESCRIPTION OF THE REFERENCE CHARACTERS

10 frame
100 probe card
11 upper guide
11H guide hole
12 lower guide
12H guide hole
13 fixation plate
13H opening
14 wiring board
14P probe connection pad
20 probe
20B probe intermediate body
20c contact portion
20m elastically-deformable portion
20t terminal portion
30 abrasive
31 abrasive sheet base
32 abrasive sheet
32K hard abrasive particle
32N binder
50 base
C electrode
K hard portion
N soft portion
L range
TC tester connection electrode
W semiconductor wafer
Z buckling direction
RE1 first resist layer
RE2 second resist layer
RE3 third resist layer
M1 first plating layer
M2 second plating layer
M3 third plating layer

1-14. (canceled)

15. A probe comprising:
a first metal portion made of first metal having conductivity; and
a plate-shaped second metal portion made of second metal having conductivity and harder than the first metal portion, the second metal portion being buried in the first metal portion and protruding from a tip of the first metal portion so as to have a contact portion to contact with an inspection target, wherein
the contact portion has such a flattened and sharpened tongue shape that a contour of a tip portion in a first cross-section along a protruding direction of the second metal portion has a first parabolic shape and a contour of the tip portion in a second cross-section along the protruding direction and perpendicular to the first cross-section has a second parabolic shape different from the first parabolic shape.

16. The probe according to claim 15, wherein
a contour of a cross-section perpendicular to the protruding direction at an end of the second metal portion buried in the first metal portion has a rectangular shape.

17. The probe according to claim 16, wherein
a long side of the rectangular shape is not greater than 10 μm and a short side thereof is not greater than 5 μm.

18. The probe according to claim 15, wherein
a first radius R2 of curvature at a vertex of the first parabolic shape of the contact portion is greater than a second radius R1 of curvature at a vertex of the second parabolic shape of the contact portion.

19. The probe according to claim 18, wherein
a ratio of the second radius R1 of curvature and the first radius R2 of curvature is 1:2 to 1:4.

20. A probe card comprising a plurality of the probes according to claim 15.

21. The probe card according to claim 20, wherein
a width direction of the first cross-section is a predetermined buckling direction of each probe.

22. A probe manufacturing method comprising:
a probe intermediate body formation step of forming a probe intermediate body in which, on one end side of a first metal portion made of a first metal having conductivity, a second metal portion made of second metal having conductivity and harder than the first metal portion is buried in a plate shape; and
a polishing step of thrusting the one end side of the first metal portion of the probe intermediate body into an abrasive the second metal portion protrudes from the first metal portion and a protruding tip has such a flattened and sharpened tongue shape that a contour of a tip portion in a first cross-section along a protruding direction of the second metal portion has a first parabolic shape and a contour of a tip portion in a second cross-section along the protruding direction and perpendicular to the first cross-section has a second parabolic shape different from the first parabolic shape.
